(19) United States
(12) Patent Application Publication
(10) Pub. No.: US 2008/0019100 A1
(43) Pub. Date: Jan. 24, 2008

(54) Plug module base with heat dissipating element

(75) Inventor: Haven Yang, Taipei County (TW)

Correspondence Address: HAVEN YANG, 20525 Via Talavera, Yorba Linda, CA, 92887, US

(73) Assignee: All Best Electronics Co., Ltd.

(21) Appl. No.: 11/487,738

(22) Filed: Jul. 18, 2006

(51) Int. Cl. H05K 7/20

(52) U.S. Cl. 361/716

(57) ABSTRACT

The present invention discloses a plug module base with a heat dissipating element that forms at least one gap by a plurality of plug passages and a heat dissipating element installed in the gap, such that the plug passages and the heat dissipating element can be used to form the plug module base with the heat dissipating element.

### FIELD OF THE INVENTION

The present invention relates to a plug module base, and more particularly to a plug having a heat dissipating element installed at a gap between plug passages.

### BACKGROUND OF THE INVENTION

At present, industries require a large quantity of electronic devices, and most of the electronic devices are connected by plugs. As the quantity of data is increased drastically and the multimedia technologies are well developed, a high-speed data transmission becomes very important. However, high-speed data transmissions are accompanied with the production of a large quantity of waste heat, and such heat causes an increase of temperature and an interference of signals, and thus affecting the transmission rate. Particularly in the case of connecting several plugs, heat cannot be dissipated effectively and will be accumulated at certain part in the assembly of the electronic device and the temperature in the assembly of the electronic device will become too high. As a result, the performance, stability and life of the electronic device will be affected adversely.

The present invention intends to find a way of producing a plug module base to effectively dissipate the heat in the plug module base and avoid the internal temperature of the electronic device from rising.

### SUMMARY OF THE INVENTION

In view of the foregoing shortcomings of the prior art plug module base, the inventor of the present invention based on years of experience in the related field to conduct extensive researches and experiment, and finally developed a plug module base with a heat dissipating element in hope of achieving the effect of dissipating a large quantity of heat quickly.

Therefore, it is a primary objective of the present invention to provide a plug module base that installs a heat dissipating element between plug passages to achieve the effect of improving the heat dissipating efficiency. To achieve the foregoing objective, the invention provides a plug module base comprising: at least two plug passages, each for containing a plug module; a plug base disposed at an end of the plug module base and electrically coupled to the plug module; a heat dissipating element containing space disposed between every two plug passages; and a heat dissipating element installed at the heat dissipating element containing space to constitute a plug module base with a good heat dissipating effect.

### BRIEF DESCRIPTION OF THE DRAWINGS

FIG. 1 is an exploded view of a plug module base with a heat dissipating element according to a preferred embodiment of the invention;

FIG. 2 is a schematic view of an assembled plug module base with a heat dissipating element according to a preferred embodiment of the invention;

FIG. 3 is a cross-sectional side view of a plug module base with a heat dissipating element according to a preferred embodiment of the invention;

FIG. 4 is an exploded view of a plug module base with a heat dissipating element according to another preferred embodiment of the invention;

FIG. 5 is an exploded view of a plug module base with a heat dissipating element according to a further preferred embodiment of the invention;

FIG. 6 is a schematic view of an assembled plug module base with a heat dissipating element according to a further preferred embodiment of the invention;

FIG. 7 is a side view of a plug module base with a heat dissipating element and four plug passages according to a preferred embodiment of the invention;

FIG. 8 is a side view of a plug module base with a heat dissipating element and eight plug passages according to a preferred embodiment of the invention;

FIG. 9 is a side view of a plug module base with a heat dissipating element and two plug passages according to a preferred embodiment of the invention;

FIG. 10 is a side view of a plug module base with a heat dissipating element and four plug passages according to a further preferred embodiment of the invention; and

FIG. 11 is a side view of a plug module base with a heat dissipating element and eight passages according to a further preferred embodiment of the invention

### DETAILED DESCRIPTION OF THE PREFERRED EMBODIMENTS

To make it easier for our examiner to understand the objective of the invention, its structure, innovative features, and performance, we use a preferred embodiment together with the attached drawings for the detailed description of the invention.

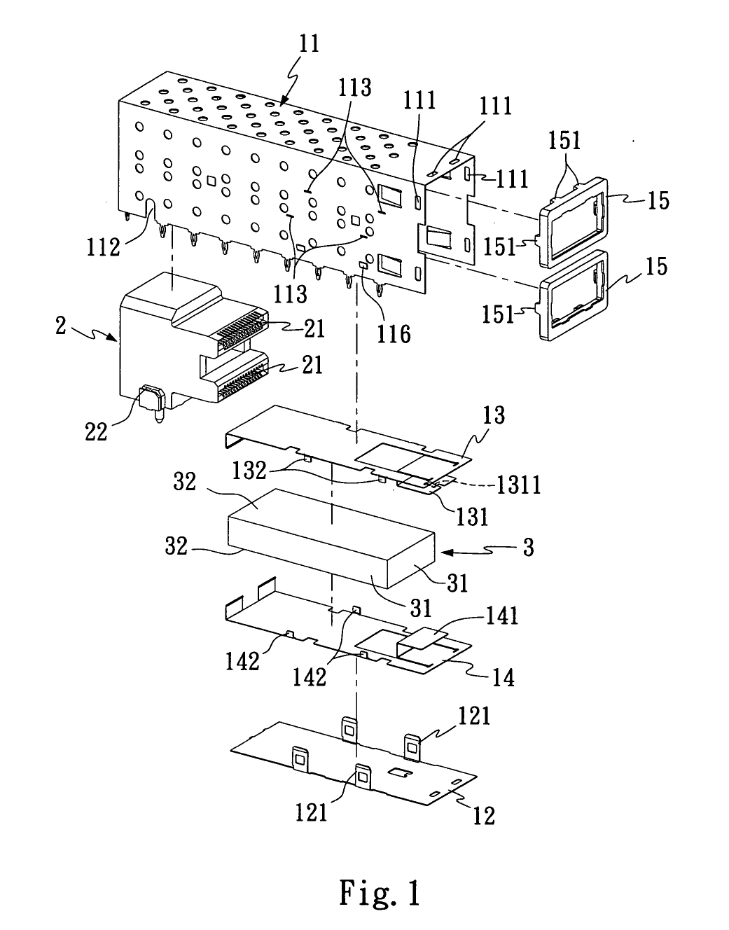

Referring to FIG. 1 to an exploded view of a plug module base with a heat dissipating element according to a preferred embodiment of the present invention, the plug module base 1 comprises two plug passages, a heat dissipating element 3 and a base 2 having two plug grooves 21; and a plug slot 15 having a latch 151 latched at a latch hole 111 of an upper casing 11, such that the plug slot 15 is fixed to the upper casing 11. The upper casing 11 has a fixing groove 112 for latching a base fixture 22 of the base 2, and the base 2 has two plug grooves 21. The upper casing 11 further includes a connecting hole 113 for latching a latch 132 of a first guiding plate 13 with a latch 142 of a second guiding plate 14. A lower cover 12 has a lower cover plate latched to a third latch 116 of the upper casing 11, such that the first guiding plate 13, second guiding plate 14 and lower cover 12 are coupled to form two plug passages. The first guiding plate 13 includes a first bent plate 131 having a latch 1311 latched with a second bent plate 141 of the second guiding plate 14, such that the first guiding plate 13 and second guiding plate 14 form a containing space for accommodating the heat dissipating element 3. The heat dissipating element 3 has two heat absorbing surfaces 32 and four heat dissipating surfaces 31, so that the two heat absorbing surfaces 32 can absorb and conduct heat to the four heat dissipating surfaces 31 for the heat dissipation, and the heat dissipating element 3 is made of graphite, ceramics, porcelain, or copper or any combination of the above.

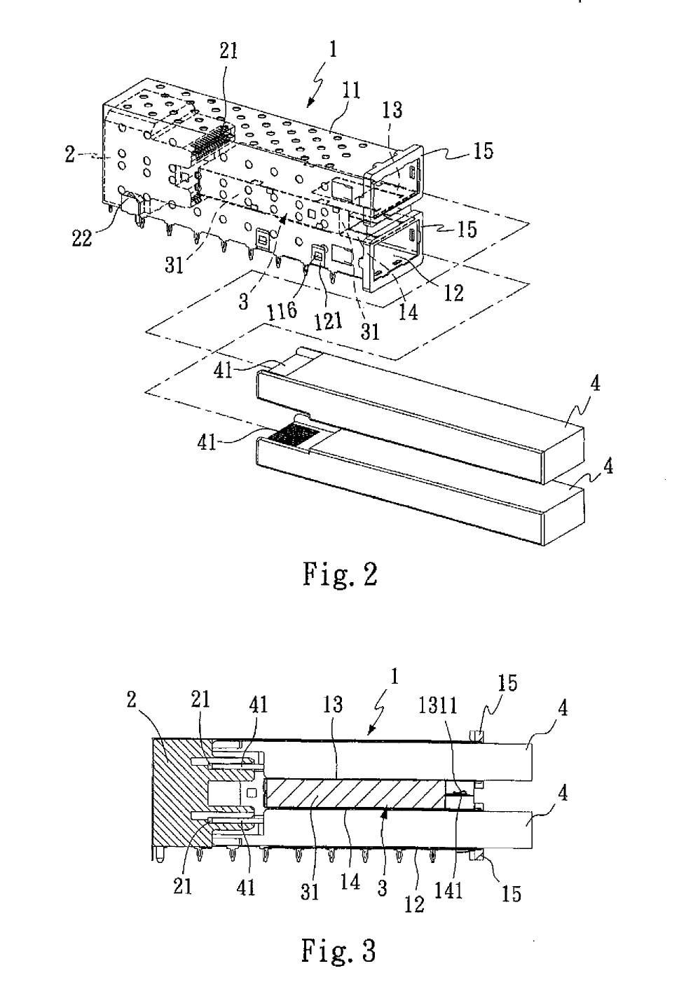

Referring to FIG. 2 for the schematic view of a plug module base with a heat dissipating element according to a preferred embodiment of the present invention, which is also an assembled structure as depicted in FIG. 1, a plug electronic device 4 is passed through the plug slot 15 and inserted into the plug module base 1, and a transmitting end 41 of the electronic device 4 is electrically coupled to the plug groove 21, so that the data in the plug electronic device 4 can be transmitted from the transmitting end 41 of the electronic device 4 and the plug groove 21, and the heat produced by the plug electronic device 4 is conducted from the heat absorbing surface 32 of the heat dissipating element 3 to the heat dissipating surface 31 and dissipated from the heat dissipating surface 31 to the atmosphere.

Referring to FIG. 3 for the cross-sectional side view of a plug module base with a heat dissipating element according to a preferred embodiment of the present invention, which is also an assembled structure as depicted in FIG. 1, a plug of the electronic device 4 is inserted from a plug slot 15 into the plug module base 1, and a transmitting end 41 of the electronic device 4 is coupled with a plug groove 21 on the base 2, and the heat produced by the electronic device 4 is conducted from a heat absorbing surface 32 of the heat dissipating element 3 to a heat dissipating surface 31 and dissipated from the heat dissipating surface 31 to the atmosphere.

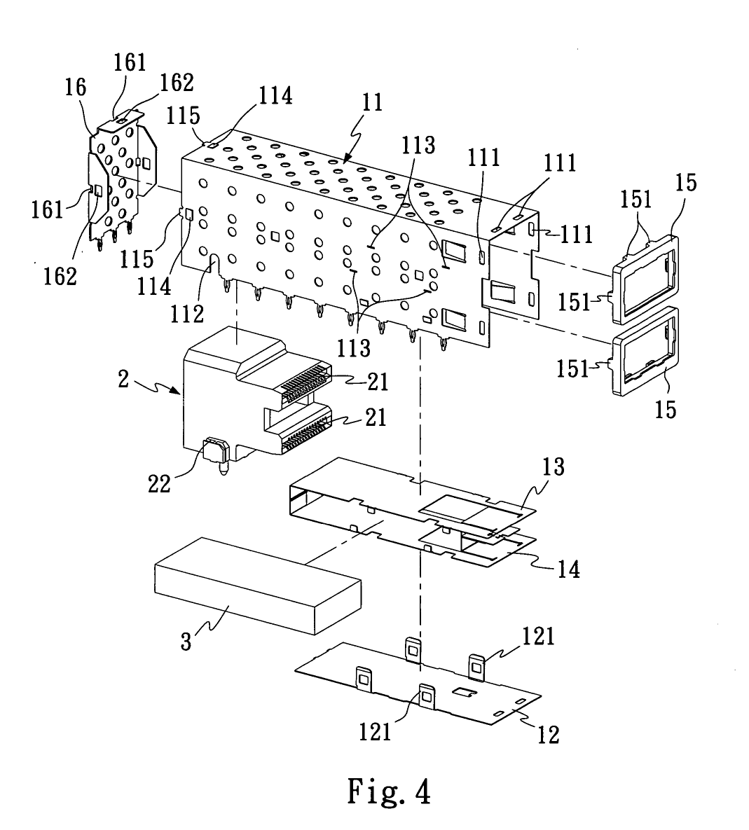

Referring to FIG. 4 for the exploded view of a plug module base with a heat dissipating element according to another preferred embodiment of the present invention, this embodiment is similar to the one illustrated in FIG. 1, and their difference resides on the upper casing 11 is not made by bending a single sheet material, but a back cover 16 is fixed at the upper casing having an n-shape cross section and an end without the plug slot 15, such that a first latch 115 of the upper casing 11 is latched into a first connecting hole 161 of the back cover 16, and a second connecting hole 162 of the back cover 16 is latched to a second latch 114 of the upper casing 11 to fix the back cover 16 onto the upper casing 11.

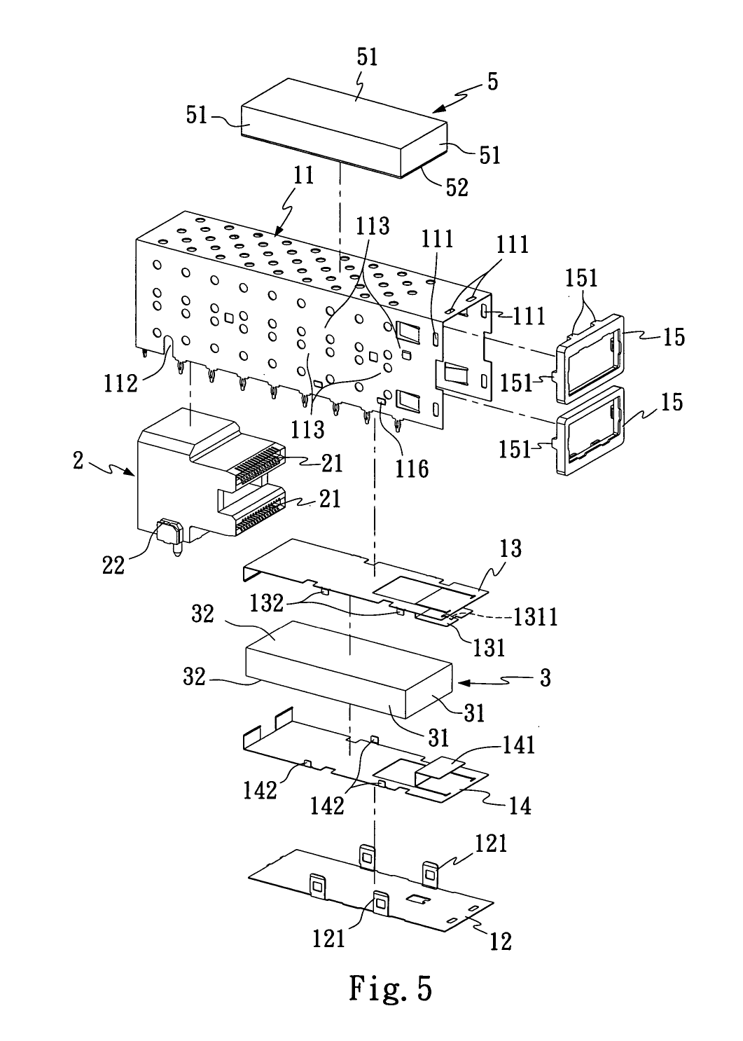

Referring to FIG. 5 for the exploded view of a plug module base with a heat dissipating element according to a further preferred embodiment of the present invention, this embodiment is similar to the one illustrated in FIG. 1 and their difference resides on that an external heat dissipating element 5 is installed onto the upper casing 11, such that after the heat produced by the electronic device 4 is conducted to the upper casing 11, the heat will be conducted from an external heat absorbing surface 52 of the external heat dissipating element 5 to an external heat dissipating surface 51 and dissipated from the external heat dissipating surface 51 to the atmosphere. This embodiment increases the heat dissipating area of the upper casing 11 and improves the heat dissipating efficiency.

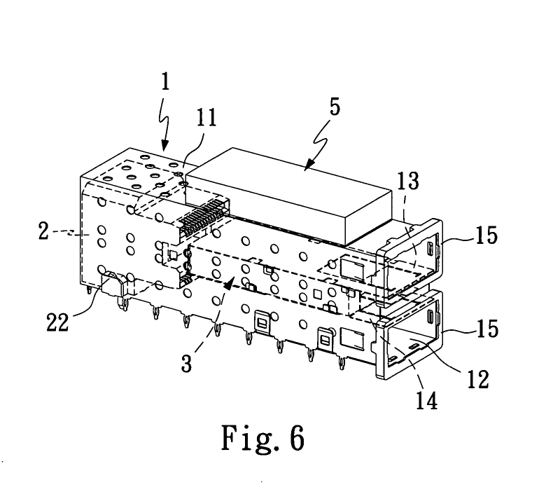

Referring to FIG. 6 for the schematic view of a plug module base with a heat dissipating element according another further preferred embodiment of the present invention, which is also an assembled structure as depicted in FIG. 1, the heat produced by the electronic components in the plug module base 1 can be dissipated from the heat dissipating element 3 and the external heat dissipating element 5 to the atmosphere quickly.

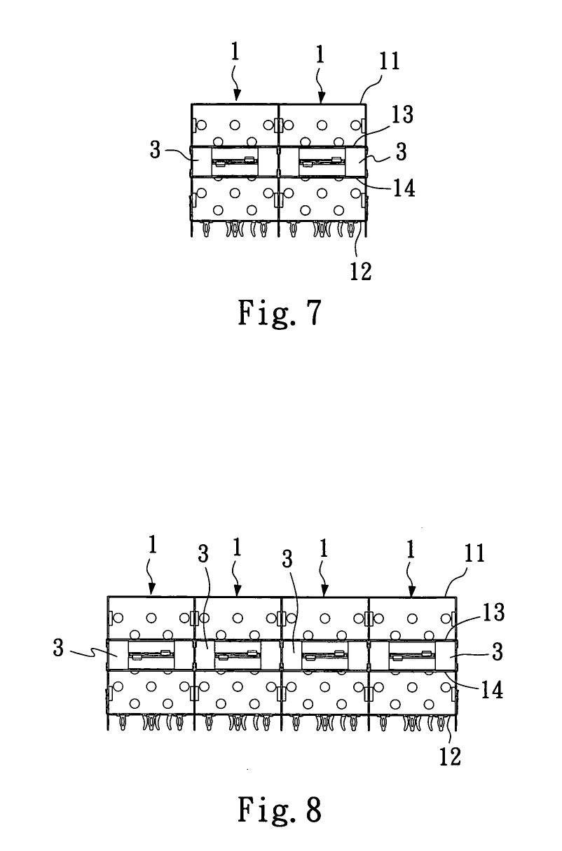

Referring to FIG. 7 for the side view of a plug module base with a heat dissipating element and four plug passages according to a preferred embodiment of the present invention which is comprised of a plug module base 1 as depicted in FIG. 1, this embodiment adopts two plug module bases 1 coupled in parallel with each other.

Referring to FIG. 8 for the side view of a plug module base with a heat dissipating element and eight plug passages according to another preferred embodiment of the present invention which is comprised of a plug module base 1 as depicted in FIG. 1, this embodiment adopts a plug module base 1 coupled in parallel with the plug electronic device 4.

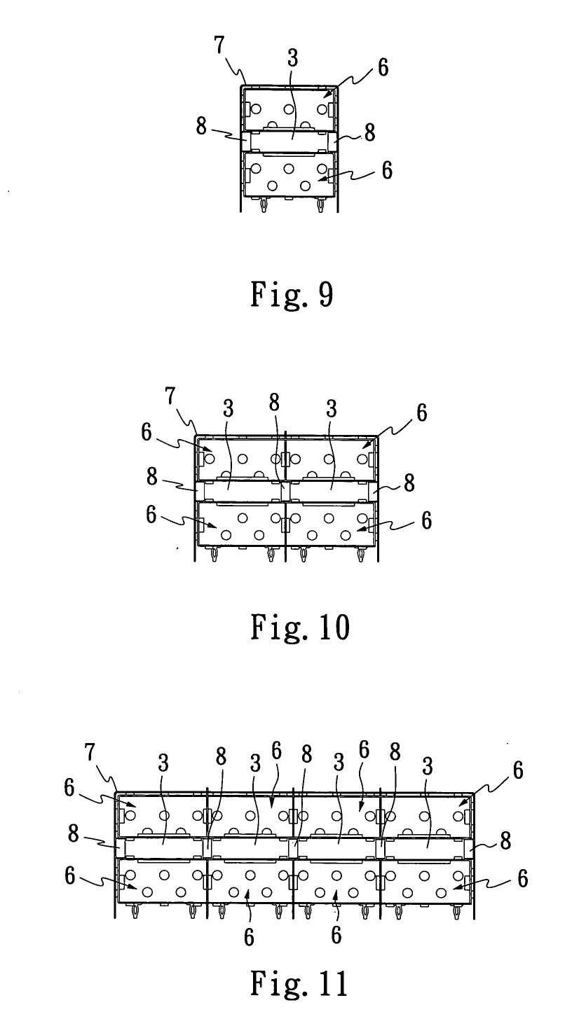

Referring to FIG. 9 for the side view of a plug module base with a heat dissipating element and two plug passages according to another further preferred embodiment of the present invention which is comprised of two plug passages 6, a plurality of support pillars 8 are arranged at the top, the bottom and the middle of two plug passages for defining a space for containing the heat dissipating element 3, and the whole structure is covered by a housing 7.

Referring to FIG. 10 for the side view of a plug module base with a heat dissipating element and four plug passages according to another preferred embodiment of the present invention, two plug passages 6 are arranged at the top and the bottom in parallel with each other, and the middle is separated by the support pillar 8, wherein the space so formed is provided for containing the heat dissipating element 3, and the whole structure is covered by the housing 7.

Referring to FIG. 11 for the side view of a plug module base with a heat dissipating element and eight plug passages according to another preferred embodiment of the present invention, four plug passages 6 are arranged at the top and the bottom in parallel with each other, and the middle is separated by the support pillar 8, wherein the space so formed is provided for containing the heat dissipating element 3, and the whole structure is covered by the housing 7.

In summation of the description above, the present invention complies with the patent application requirements. The present invention installs the heat dissipating elements at the plug module base inside or outside the housing to improve the heat dissipating efficiency, and enhances the performance over the conventional structure and thus is duly filed for patent application.

1. A plug module base with a heat dissipating element, comprising:
at least two plug passages arranged vertically, each being used for containing a plug module and having a plug base disposed at an end of said each plug passage and electrically coupled to said plug module, and a heat dissipating element containing space disposed vertically between every two of said plug passages, and
a heat dissipating element, installed in said heat dissipating element containing space.

2. The plug module base of claim 1, wherein said each plug passage has at least one first latch for latching at least one second latch of said plug module.

3. The plug module base of claim 1, wherein said at least two plug bases are disposed on a base.

4. The plug module base of claim 1, wherein said two plug passages are comprised of an upper casing, a lower cover and two guiding plates, said two guiding plates being parallel to said upper casing and lower cover, and said heat dissipating element containing space is disposed between said two guiding plates,

5. The plug module base of claim 4, wherein said upper casing is made by bending a metal sheet into a metal casing with an reshape cross section.

6. The plug module base of claim 4, further comprising a blocking plate disposed on a distal surface of metal casing having an n-shape cross section.

7. The plug module base of claim 4, wherein said lower cover, said two guiding plates, two plug slots and said base are fixed to said upper casing by a latch.

8. The plug module base of claim 1, wherein said two plug passages comprise two single plug passages and a plurality of support pillars, and said heat dissipating element containing space is disposed between said plurality of support pillars.

9. The plug module base of claim 1, wherein said heat dissipating element is one selected from the collection of graphite, ceramics, porcelain, and copper or any combination of the above.

10. The plug module base of claim 4, further comprising at least one auxiliary heat dissipating element disposed at an external side of said upper casing.

11. The plug module base of claim 10, further comprising a silica gel disposed between said upper casing and said auxiliary heat dissipating element.

12. The plug module base of claim 10, wherein said auxiliary heat dissipating element is one selected from the collection of graphite, ceramics, porcelain, and copper or any combination of the above.

13. The plug module base of claim 1, wherein said heat dissipating element has an upper surface and a lower surface, each in contact with one of said plug modules for absorbing heat, said heat dissipating element having side surfaces for dissipating heat.
